(19) United States
(12) Patent Application Publication
(10) Pub. No.: US 2008/0121881 A1
(43) Pub. Date: May 29, 2008

(54) SEMICONDUCTOR DEVICE

(76) Inventors: Shinichi Kaneko, Osaka (JP); Shigeru Yano, Shiga (JP)

Correspondence Address: MCDERMOTT WILL & EMERY LLP, 600 13TH STREET, NW, WASHINGTON, DC, 20005-3096, US

(21) Appl. No.: 11/945,637

(22) Filed: Nov. 27, 2007

(30) Foreign Application Priority Data
Nov. 28, 2006 (JP) 2006-319600

(51) Int. Cl. H01L 23/58

(52) U.S. Cl. 257/48; 257/E23.002

(57) ABSTRACT

A semiconductor device includes a power device formed on a semiconductor substrate; a plurality of transistors formed on the semiconductor substrate; a first insulating film formed on the semiconductor substrate so as to cover the power device and the plurality of transistors; an interconnect layer formed on the first insulating film and including a second insulating film, an interconnect formed in the second insulating film and dummy patterns formed in the second insulating film in a region where the interconnect is not formed; and a power electrode corresponding to an uppermost layer interconnect formed on the interconnect layer and electrically connected to the power device. It further includes uppermost layer dummy patterns uniformly provided on the interconnect layer in a region where the uppermost layer interconnect is not formed.

### CROSS-REFERENCE TO RELATED APPLICATIONS

This application claims priority under 35 U.S.C. §119 on Patent Application No. 2006-319600 filed in Japan on Nov. 28, 2006, the entire contents of which are hereby incorporated by reference.

### BACKGROUND OF THE INVENTION

The present invention relates to a semiconductor device, and more particularly, it relates to a semiconductor device including an uppermost layer interconnect with a large thickness.

In conventional technique, interconnect dummy patterns are occasionally formed in order to reduce stress concentration caused by density variation of interconnect patterns in chemical mechanical polishing (CMP) performed for planarizing an interlayer insulating film used for insulating a lower layer interconnect from an upper layer interconnect in multilayered interconnects formed on a semiconductor substrate.

Now, a conventional semiconductor device including an interconnect layer having dummy patterns will be described with reference to FIGS. 10 and 11 (see, for example, Patent Document 1: Japanese Laid-Open Patent Publication No. 2006-140326). FIG. 10 is a plan view for showing the structure of the conventional semiconductor device. Also, FIG. 11 is an enlarged cross-sectional view of the conventional semiconductor device taken on line XI-XI of FIG. 10.

As shown in FIG. 10, a power electrode 629 corresponding to an uppermost layer interconnect is formed on a semiconductor chip 600, and a bonding pad 630 corresponding to the uppermost layer interconnect is formed in a peripheral portion on the semiconductor chip 600.

As shown in FIG. 11, gate electrodes 602, 602a and 602b are formed on a semiconductor substrate 601, and source/drain regions 603, 603a and 603b are formed in the semiconductor substrate 601 respectively on both sides of the gate electrodes 602, 602a and 602b.

An insulating film 604 is formed on the semiconductor substrate 601 so as to cover the gate electrodes 602, 602a and 602b, and a contact plug 605 electrically connected to the source/drain region 603 and a contact plug 606 electrically connected to the gate electrode 602 are formed in the insulating film 604.

A first interconnect layer composed of a first insulating film 607, interconnects 608, 609 and 610 and first dummy patterns 611 is formed on the insulating film 604. Specifically, as shown in FIG. 11, the interconnect 608 electrically connected to the contact plug 605, the interconnect 609 electrically connected to the contact plug 606 and the interconnect 610 electrically connected to an internal circuit (not shown) are formed in the first insulating film 607. Furthermore, the first dummy patterns 611 are uniformly provided in a non-interconnect region of the first insulating film 607 (namely, a region of the first insulating film 607 where none of the interconnects 608, 609 and 610 is formed).

A first interlayer insulating film 612 is formed on the first interconnect layer, and a contact plug 613 electrically connected to the interconnect 608 and a contact plug 614 electrically connected to the interconnect 610 are formed in the first interlayer insulating film 612.

A second interconnect layer composed of a second insulating film 615, interconnects 616, 617 and 618 and second dummy patterns 619 are formed on the first interlayer insulating film 612. Specifically, as shown in FIG. 11, the interconnect 616 electrically connected to the contact plug 613, the interconnect 617 electrically connected to the contact plug 614 and the interconnect 618 electrically connected to an internal circuit (not shown) are formed in the second insulating film 615. Also, the second dummy patterns 619 are uniformly provided in a non-interconnect region of the second insulating film 615 (namely, a region of the second insulating film 615 where none of the interconnects 616, 617 and 618 is formed).

A second interlayer insulating film 620 is formed on the second interconnect layer, and a contact plug 621 electrically connected to the interconnect 616 and a contact plug 622 electrically connected to the interconnect 618 are formed in the second interlayer insulating film 620.

A third interconnect layer composed of a third insulating film 623, interconnects 624 and 625 and third dummy patterns 626 are formed on the second interlayer insulating film 620. Specifically, as shown in FIG. 11, the interconnect 624 electrically connected to the contact plug 621 and the interconnect 625 electrically connected to the contact plug 622 are formed in the third insulating film 623. Also, the third dummy patterns 626 are uniformly disposed in a non-interconnect region of the third insulating film 623 (namely, in a region of the third insulating film 623 where none of the interconnects 624 and 625 is formed).

A third interlayer insulating film 627 is formed on the third interconnect layer, and a contact plug 628 electrically connected to the interconnect 624 is formed in the third interlayer insulating film 627.

The power electrode 629 corresponding to the uppermost layer interconnect electrically connected to the contact plug 628 and the bonding pad 630 corresponding to the uppermost layer interconnect are formed on the third interlayer insulating film 627. A passivation film 632 is formed on the third interlayer insulating film 627 so as to cover the power electrode 629 and expose a wire bonding portion of the bonding pad 630.

In this manner, the conventional semiconductor device includes, as shown in FIG. 11, a power transistor (power device) Tr electrically connected to the power electrode 629 with a large thickness and a large width and a plurality of transistors Tr1 and Tr2 (merely two of which are representatively shown in FIG. 11 for simplification) formed on the semiconductor substrate 601.

In the conventional semiconductor device, since the dummy patterns 611, 619 and 626 are uniformly provided respectively in the non-interconnect regions of the insulating films 607, 615 and 623 as shown in FIG. 11, stress concentration caused by density variation of the interconnect patterns can be reduced in the CMP performed on the interlayer insulating films 612, 620 and 627.

On the other hand, the passivation film 632 is not subjected to the CMP because there is little need to perform the CMP on the passivation film 632 since no interconnect is formed on the passivation film 632 and because the fabrication cost is increased if the passivation film 632 is subjected to the CMP. Therefore, no dummy pattern is formed for the uppermost layer interconnect as shown in FIGS. 10 and 11.

The conventional semiconductor device has, however, the following problem, which will be described with reference to FIGS. 12 and 13: FIG. 12 is an enlarged plan view for showing the structures of the transistors Tr1 and Tr2 used in the conventional semiconductor device. FIG. 13 is a diagram for showing the relationships between a gate-source voltage V_{GS} and drain currents I_{D} and I_{D}′.

As shown in FIG. 12, the transistor Tr1 includes the gate electrode 602a formed on the semiconductor substrate (not shown) and the source/drain regions 603a formed in the semiconductor substrate on both sides of the gate electrode 602a. Similarly, the transistor Tr2 includes the gate electrode 602b formed on the semiconductor substrate and the source/drain regions 603b formed in the semiconductor substrate on both sides of the gate electrode 602b.

At this point, since the power electrode 629 corresponding to the uppermost layer interconnect has a larger thickness and a larger width than each of the interconnects formed in the respective insulating films 607, 615 and 623, thermal stress caused by the power electrode 629 is larger than that caused by the interconnect, and therefore, the influence on a transistor of the thermal stress caused by the power electrode 629 is larger than the influence on the transistor of the thermal stress caused by the interconnect. In particular, when the power electrode 629 is made of Cu and the interconnect is made of Al, the thermal stress caused by the power electrode 629 is much larger than the thermal stress caused by the interconnect, so that the influence on the transistor of the thermal stress caused by the power electrode 629 cannot be ignored.

The influence on a transistor of the thermal stress caused by the power electrode 629 will now be described.

Since the transistor Tr1 is closer to the power electrode 629 than the transistor Tr2, the thermal stress σ₁ applied by the power electrode 629 to the transistor Tr1 is larger than the thermal stress σ₂ applied by the power electrode 629 to the transistor Tr2 as shown in FIG. 12. Therefore, change ΔL₁ in the gate length of the gate electrode 602a caused by the thermal stress σ₁ is larger than change ΔL₂ in the gate length of the gate electrode 602b caused by the thermal stress σ₂.

At this point, assuming that the designed gate length of the gate electrodes 602a and 602b is L and that the designed gate width of the gate electrodes 602a and 602b is W, gate lengths L₁ and L₂ of the transistors Tr1 and Tr2 having changed through the influence of the thermal stress σ₁ and σ₂ are as follows:

L₁=L+ΔL₁

L₂=L+ΔL₂

In this manner, the thermal stress applied by the power electrode 629 to each transistor depends upon a distance of the transistor from the power electrode 629, and a transistor closer to the power electrode 629 is more largely affected by the thermal stress caused by the power electrode 629 and its gate length is more largely shifted from the designed gate length L.

At this point, assuming that the drain current is I_{D}, that the mobility of electrons (or holes) is μ, that the gate capacity per unit area is C_{OX}, that the gate width is W, that the gate length is L, that the gate-source voltage is V_{GS}, and that the threshold voltage is Vₜₕ, the drain current I_{D} is represented by the following Equation 1:

$${I}_{D} = \frac{μ {C}_{OX} }{2} \frac{W}{L} {( {V}_{GS} - {V}_{th} )}^{2} \qquad Equation 1$$

When the drain current I_{D} is plotted on the ordinate and the gate-source voltage V_{GS} is plotted on the abscissa on the basis of Equation 1, a curve A as shown in FIG. 13 is obtained.

Also, when the change in the gate length L caused by the thermal stress of the power electrode is ΔL, a drain current I_{D}′ obtained through the change is represented by the following Equation 2:

$${I}_{{D}^{′}} = \frac{μ {C}_{OX}}{2} \frac{W}{( L + L )} {( {V}_{GS} - {V}_{th} )}^{2} \qquad Equation 2$$

In the case where, for example, the change ΔL is larger than 0, when the drain current I_{D}′ is plotted on the ordinate and the gate-source voltage V_{GS} is plotted on the abscissa, a curve B as shown in FIG. 13 is obtained.

As shown in FIG. 13, the curve B of the drain current I_{D}′ obtained through the change is shifted in the rightward direction from the curve A of the designed drain current I_{D}, and the drain current I_{D}′ obtained through the change is smaller than the designed drain current I_{D}.

Since the thermal stress applied to each transistor by the power electrode is thus varied depending upon the distance of the transistor from the power electrode, a transistor closer to the power electrode has a transistor characteristic more largely shifted from the designed transistor characteristic. Therefore, although respective transistors are designed to have the identical transistor characteristic, there arises a problem that the actual transistor characteristic is varied among the transistors.

Although the above description is given on the specific example where the thermal stress σ₁ and σ₂ caused by the power electrode 629 is applied to the transistors Tr1 and Tr2 along the gate length direction as shown in FIG. 12, a similar problem arises also when the thermal stress caused by the power electrode is applied to the transistors along the gate width direction. Specifically, since a transistor closer to the power electrode is more largely affected by the thermal stress caused by the power electrode, the gate width of the transistor is more largely shifted from the designed gate width, and hence, the transistor characteristic is more largely shifted from the designed transistor characteristic. Accordingly, although the respective transistors are designed to have the identical transistor characteristic, there arises a problem that the actual transistor characteristic is varied among the transistors.

### SUMMARY OF THE INVENTION

In consideration of the aforementioned conventional problem, an object of the invention is preventing variation in the transistor characteristic among transistors in a semiconductor device including an uppermost layer interconnect with a large thickness.

In order to achieve the object, the semiconductor device according to one aspect of the invention includes a power device formed on a semiconductor substrate; a plurality of transistors formed on the semiconductor substrate; a first insulating film formed on the semiconductor substrate so as to cover the power device and the plurality of transistors; an interconnect layer formed on the first insulating film and including a second insulating film, an interconnect formed in the second insulating film and dummy patterns formed in the second insulating film in a region where the interconnect is not formed; a power electrode corresponding to an uppermost layer interconnect formed on the interconnect layer and electrically connected to the power device; and uppermost layer dummy patterns uniformly provided on the interconnect layer in a region where the uppermost layer interconnect is not formed.

In the semiconductor device of this aspect of the invention, since the uppermost layer dummy patterns are uniformly provided on the interconnect layer in the region where the uppermost layer interconnect is not formed, thermal stress caused by the uppermost layer dummy patterns can be uniformly applied to transistors disposed in the region where the uppermost layer interconnect is not formed among all transistors formed on the semiconductor substrate. On the other hand, thermal stress caused by the uppermost layer interconnect is applied to transistors disposed in a region where the uppermost layer interconnect is formed. Therefore, the thermal stress can be uniformly applied to the respective transistors. As a result, even when the transistor characteristics of the transistors are varied through influence on the transistors of the thermal stress, the transistor characteristics of the transistors can be uniformly varied, so as to prevent variation in the transistor characteristic among the transistors.

In the semiconductor device according to another aspect of the invention, the uppermost layer interconnect preferably has a larger thickness than the interconnect, and specifically, the uppermost layer interconnect preferably has a thickness, for example, three times or more as large as a thickness of the interconnect.

When the power electrode corresponding to the uppermost layer interconnect thus has a larger thickness than the interconnect, the thermal stress caused by the power electrode largely affects the transistors, and hence, the invention is more effectively practiced.

In the semiconductor device according to another aspect of the invention, the uppermost layer interconnect is preferably made of Cu.

When the power electrode corresponding to the uppermost layer interconnect is thus made of Cu, the thermal stress caused by the power electrode comparatively largely affects the transistors, and hence, the invention is more effectively practiced.

In the semiconductor device according to another aspect of the invention, the power electrode preferably has a slit.

When the power electrode thus has a slit, the thermal stress caused by the power electrode can be uniformly applied to transistors disposed below the power electrode among a plurality of transistors formed on the semiconductor substrate, and hence, the thermal stress can be more uniformly applied to the respective transistors.

The semiconductor device according to another aspect of the invention preferably further includes a bonding pad corresponding to the uppermost layer interconnect formed on the interconnect layer.

In this case, the bonding pad preferably has a slit.

When the bonding pad thus has a slit, thermal stress caused by the bonding pad can be uniformly applied to transistors disposed below the bonding pad among the plural transistors formed on the semiconductor substrate, and hence, the thermal stress can be more uniformly applied to the respective transistors.

In the semiconductor device according to another aspect of the invention, the uppermost layer dummy patterns are preferably uniformly provided in a region of the second insulating film where the interconnect is not formed excluding a region disposed below the bonding pad.

Thus, the parasitic capacitance between the bonding pad and the semiconductor substrate can be prevented from being increased by dummy patterns disposed below the bonding pad.

The semiconductor device according to another aspect of the invention preferably further includes a testing monitor pad corresponding to the uppermost layer interconnect formed on the interconnect layer, and the testing monitor pad is preferably provided to be distinguishable from the uppermost layer dummy patterns. For example, the testing monitor pad is preferably in a different shape from the uppermost layer dummy patterns.

Thus, the testing monitor pad can be easily discriminated from the uppermost layer dummy patterns.

As described so far, in the semiconductor device according to an aspect of the invention, since the uppermost layer dummy patterns are uniformly provided on the interconnect layer in the region where the uppermost layer interconnect is not formed, thermal stress caused by the uppermost layer dummy patterns can be uniformly applied to transistors disposed in the region where the uppermost layer interconnect is not formed among all transistors formed on the semiconductor substrate. On the other hand, thermal stress caused by the uppermost layer interconnect is applied to transistors disposed in a region where the uppermost layer interconnect is formed. Therefore, the thermal stress can be uniformly applied to the respective transistors. As a result, even when the transistor characteristics of the transistors are varied through the influence on the transistors of the thermal stress, the transistor characteristics of the transistors can be uniformly varied, so as to prevent variation in the transistor characteristic among the transistors.

### BRIEF DESCRIPTION OF THE DRAWINGS

FIG. 1 is a plan view of a semiconductor device according to an embodiment of the invention.

FIG. 2 is an enlarged cross-sectional view of the semiconductor device according to the embodiment of the invention.

FIG. 3 is a plan view of a power electrode used in a semiconductor device according to Modification 1 of the invention.

FIG. 4 is a plan view of a bonding pad used in a semiconductor device according to Modification 2 of the invention.

FIG. 5 is a cross-sectional view for showing the structure of a bonding pad portion of the semiconductor device of Modification 2.

FIG. 6 is a cross-sectional view of a semiconductor device according to Modification 3 of the invention.

FIG. 7 is a plan view of a semiconductor device according to Modification 4 of the invention.

FIG. 8 is an enlarged cross-sectional view for showing the structure of a testing monitor pad portion of the semiconductor device of Modification 4.

FIGS. 9A, 9B and 9C are plan views for showing exemplified shapes of a testing monitor pad.

FIG. 10 is a plan view of a conventional semiconductor device.

FIG. 11 is an enlarged cross-sectional view of the conventional semiconductor device.

FIG. 12 is an enlarged plan view for showing the structures of transistors Tr1 and Tr2 used in the conventional semiconductor device.

FIG. 13 is a diagram for showing the relationships between a gate-source voltage V_{GS} and drain currents I_{D} and I_{D}′.

### DETAILED DESCRIPTION OF THE INVENTION

Now, a preferred embodiment of the invention will be described with reference to the accompanying drawings.

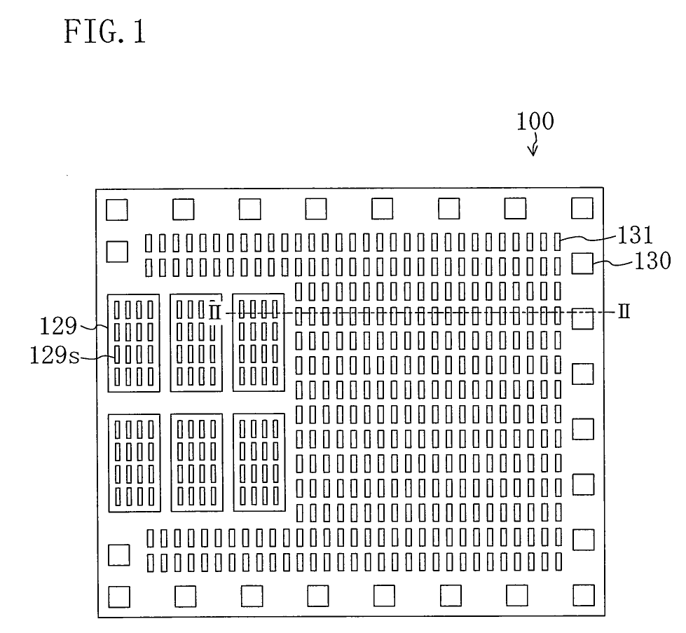

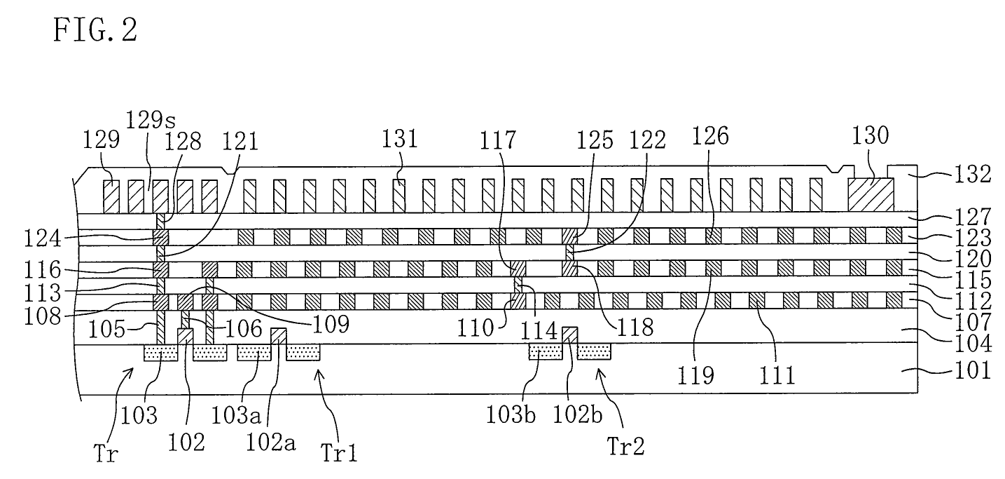

A semiconductor device according to a preferred embodiment of the invention will now be described with reference to FIGS. 1 and 2. FIG. 1 is a plan view of the semiconductor device of this embodiment and FIG. 2 is an enlarged cross-sectional view thereof taken on line II-II of FIG. 1.

As shown in FIG. 1, a power electrode 129 with a large thickness and a large width corresponding to an uppermost layer interconnect is formed on a semiconductor chip 100, and the power electrode 129 has slits 129s arranged in the form of a matrix. Also, a bonding pad 130 corresponding to the uppermost layer interconnect is formed in a peripheral portion on the semiconductor chip 100. Uppermost layer dummy patterns 131 each in a desired shape are uniformly provided in a region on the semiconductor chip 100 where none of the power electrode 129 and the bonding pad 130 is formed.

As shown in FIG. 2, gate electrodes 102, 102a and 102b are formed on a semiconductor substrate 101, and source/drain regions 103, 103a and 103b are respectively formed in the semiconductor substrate 101 on both sides of the gate electrodes 102, 102a and 102b.

An insulating film 104 is formed on the semiconductor substrate 101 so as to cover the gate electrodes 102, 102a and 102b, and a contact plug 105 electrically connected to the source/drain region 103 and a contact plug 106 electrically connected to the gate electrode 102 are formed in the insulating film 104.

A first interconnect layer composed of a first insulating film 107, interconnects 108, 109 and 110 and first dummy patterns 111 is formed on the insulating film 104. Specifically, as shown in FIG. 2, the interconnect 108 electrically connected to the contact plug 105, the interconnect 109 electrically connected to the contact plug 106 and the interconnect 110 electrically connected to an internal circuit (not shown) are formed in the first insulating film 107. At this point, the interconnects 108, 109 and 110 are made of, for example, Al. Furthermore, the first dummy patterns 111 made of Al are uniformly provided in a non-interconnect region of the first insulating film 107 (namely, a region of the first insulating film 107 where none of the interconnects 108, 109 and 110 is formed).

A first interlayer insulating film 112 made of, for example, SiO₂ is formed on the first interconnect layer, and a contact plug 113 electrically connected to the interconnect 108 and a contact plug 114 electrically connected to the interconnect 110 are formed in the first interlayer insulating film 112.

A second interconnect layer composed of a second insulating film 115, interconnects 116, 117 and 118 and second dummy patterns 119 is formed on the first interlayer insulating film 112. Specifically, as shown in FIG. 2, the interconnect 116 electrically connected to the contact plug 113, the interconnect 117 electrically connected to the contact plug 114 and the interconnect 118 electrically connected to an internal circuit (not shown) are formed in the second insulating film 115. At this point, the interconnects 116, 117 and 118 are made of, for example, Al. Also, the second dummy patterns 119 made of Al are uniformly provided in a non-interconnect region of the second insulating film 115 (namely, a region of the second insulating film 115 where none of the interconnects 116, 117 and 118 is formed).

A second interlayer insulating film 120 made of, for example, SiO₂ is formed on the second interconnect layer, and a contact plug 121 electrically connected to the interconnect 116 and a contact plug 122 electrically connected to the interconnect 118 are formed in the second interlayer insulating film 120.

A third interconnect layer composed of a third insulating film 123, interconnects 124 and 125 and third dummy patterns 126 is formed on the second interlayer insulating film 120. Specifically, as shown in FIG. 2, the interconnect 124 electrically connected to the contact plug 121 and the interconnect 125 electrically connected to the contact plug 122 are formed in the third insulating film 123. At this point, the interconnects 124 and 125 are made of, for example, Al. Also, the third dummy patterns 126 made of Al are uniformly provided in a non-interconnect region of the third insulating film 123 (namely, a region of the third insulating film 123 where none of the interconnects 124 and 125 is formed).

A third interlayer insulating film 127 made of, for example, SiO₂ is formed on the third interconnect layer, and a contact plug 128 electrically connected to the interconnect 124 is formed in the third interlayer insulating film 127.

On the third interlayer insulating film 127, the power electrode 129 corresponding to the uppermost layer interconnect electrically connected to the contact plug 128 and made of, for example, Cu and the bonding pad 130 corresponding to the uppermost layer interconnect made of, for example, Cu are formed. The power electrode 129 has the slits 129s arranged in the form of a matrix. At this point, the power electrode 129 and the bonding pad 130 corresponding to the uppermost layer interconnect have a thickness, for example, three times as large as the thickness of each interconnect formed in the insulating films 107, 115 and 123. Also, the uppermost layer dummy patterns 131 are uniformly provided in an uppermost layer non-interconnect region on the third interlayer insulating film 127 (namely, a region on the third interlayer insulating film 127 where none of the power electrode 129 and the bonding pad 130 is formed).

On the third interlayer insulating film 127, a passivation film 132 including, for example, a Si—N bond is formed so as to cover the power electrode 129 and the uppermost layer dummy patterns 131 and to expose a wire bonding portion of the bonding pad 130.

In this embodiment, the uppermost layer dummy patterns 131 are uniformly provided in the region on the third interlayer insulating film 127 where the power electrode 129 corresponding to the uppermost layer interconnect is not formed. Therefore, thermal stress caused by the uppermost layer dummy patterns 131 can be uniformly applied to transistors disposed in the region where the power electrode 129 is not formed among a plurality of transistors formed on the semiconductor substrate 101. On the other hand, thermal stress caused by the power electrode 129 is applied to transistors disposed in the region where the power electrode 129 is formed. Thus, the thermal stress applied to the respective transistors can be made uniform. In addition, since the power electrode 129 is provided with the slits 129s, the thermal stress caused by the power electrode 129 can be uniformly applied to transistors disposed below the power electrode 129 among the plural transistors formed on the semiconductor substrate 101. Therefore, the thermal stress can be more uniformly applied to the respective transistors.

In the conventional technique, the stress applied to the transistor Tr1 comparatively close to the power electrode 629 is larger than the stress applied to the transistor Tr2 comparatively farther from the power electrode 629. On the contrary, in this embodiment, the stress applied to a transistor Tr1 comparatively close to the power electrode 129 and the stress applied to a transistor Tr2 comparatively farther from the power electrode 129 can be made uniform.

Therefore, even when the transistor characteristics of the respective transistors are varied due to the influence of the thermal stress in this embodiment, the transistor characteristics of the respective transistors can be uniformly varied, so as to prevent variation in the transistor characteristics among the respective transistors.

Moreover, the following additional effect can be attained in this embodiment:

In the conventional technique, no dummy pattern is formed for the uppermost layer interconnect, and hence, a large level difference derived from the presence of the power electrode 629 or the bonding pad 630 is caused in the passivation film 632. Therefore, stress caused through thermal expansion or thermal shrinkage of a package (not shown) of, for example, a resin formed on the passivation film 632 (i.e., thermal stress caused due to a difference in the thermal expansion coefficient between the passivation film 632 and the package) is concentrated on an edge portion of each level difference in the passivation film 632 derived from the presence of the power electrode 629 or the bonding pad 630. As a result, it is apprehended that a crack may occur in the passivation film 632 or in the interlayer insulating film 627, 620 or 612 so as to cause a short-circuit between the interconnects.

On the contrary, since the dummy patterns 131 corresponding to the uppermost layer interconnect are uniformly provided in the uppermost layer non-interconnect region on the third interlayer insulating film 127 in this embodiment, level differences (not shown) derived from the presence of the uppermost layer dummy patterns 131 can be additionally caused in the passivation film 132. Therefore, stress caused through thermal expansion or thermal shrinkage of a package can be dispersed among edge portions of the level differences in the passivation film 132 derived from the presence of the uppermost layer dummy patterns 131, and hence, a short-circuit between the interconnects can be prevented. In addition, since the power electrode 129 has the slits 129s in this embodiment, level differences (not shown) derived from the presence of the slits 129s can be additionally caused in the passivation film 132. Therefore, the stress caused through the thermal expansion or the thermal shrinkage of the package can be dispersed also among edge portions of the level differences in the passivation film 132 derived from the presence of the slits 129s, and hence, a short-circuit between the interconnects can be more definitely prevented.

Furthermore, in the conventional technique, since the thermal stress derived from the difference in the thermal expansion coefficient between the power electrode 629 and the bonding pad 630 corresponding to the uppermost layer interconnect and the passivation film 632 is concentrated on the edge portions of the power electrode 629 and the bonding pad 630, it is apprehended that a crack may occur in the passivation film 632 or in the interlayer insulating film 627, 620 or 612 so as to cause a short-circuit between the interconnects. In particular, since a large current passes through the power electrode 629, the temperature is increased in a region where the power electrode 629 is formed because heat is generated therein, and therefore, it is apprehended that the thermal stress is further concentrated on the edge portion of the power electrode 629.

On the contrary, in the present embodiment, since the uppermost layer dummy patterns 131 are uniformly provided in the uppermost layer non-interconnect region on the third interlayer insulating film 127, the thermal stress can be dispersed among the edge portions of the uppermost layer dummy patterns 131, so as to prevent a short-circuit between the interconnects. In addition, since the power electrode 129 has the slits 129s in this embodiment, the number of edge portions of the power electrode 129 can be further increased. Therefore, the thermal stress can be dispersed also among the increased number of edge portions of the power electrode 129, and hence, a short-circuit between the interconnects can be more definitely prevented.

It is noted that the thermal stress σ is represented by the following Equation 3 wherein E is Young's modulus, ν is Poisson ratio, T₁ and T₂ are temperatures, and α₁ and α₂ are thermal expansion coefficients:

$$σ = \frac{E}{( 1 - ν )} {\int }_{{T}_{2}}^{{T}_{1}} ( {α}_{1} - {α}_{2} ) d T \qquad Equation 3$$

The thermal expansion coefficients of the respective composing elements of the semiconductor device of this embodiment are as follows:

Thermal expansion coefficient of a resin package: approximately 9.0×10⁻⁶/° C.

Thermal expansion coefficient of a passivation film including a Si—N bond:
approximately 2.2×10⁻⁶/° C.

Thermal expansion coefficient of an uppermost layer interconnect made of Cu:
approximately 16.5×10⁻⁶/° C.

Thermal expansion coefficient of an interconnect made of Al:
approximately 23×10⁻⁶/° C.

Thermal expansion coefficient of an interlayer insulating film made of SiO₂:
approximately 0.6×10⁻⁶ through 0.9×10⁻⁶/° C.

Although the power electrode 129 has the slits 129s in this embodiment, the invention is not limited to the slits but a power electrode with no slits may be used instead.

### Modification 1

The power electrode 129 has the slits 129s arranged in the form of a matrix as shown in FIG. 1 in the embodiment, which does not limit the invention.

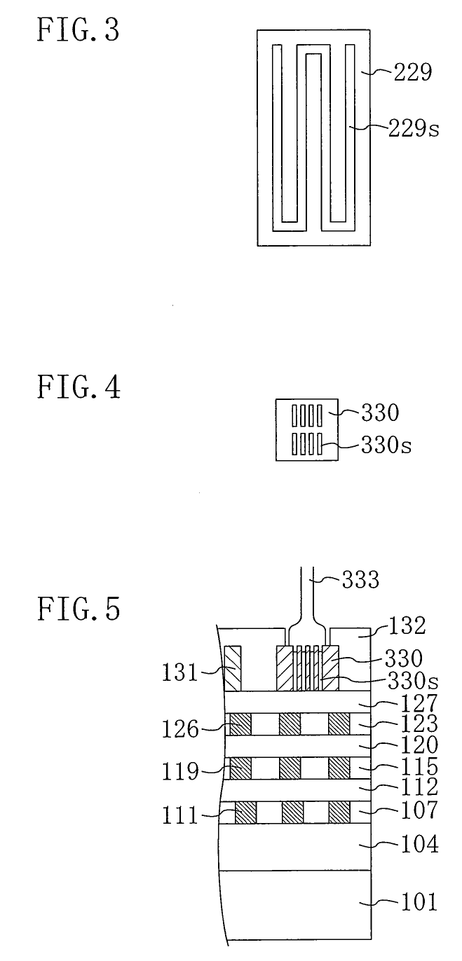

Another specific example of the power electrode having the slits will now be described with reference to FIG. 3. FIG. 3 is a plan view for showing the structure of a power electrode used in a semiconductor device according to Modification 1.

The power electrode 229 of FIG. 3 has a slit 229s continuously formed in the shape of W.

Also when the power electrode 229 having such a slit 229s is used, the aforementioned effects of the embodiment can be attained.

### Modification 2

The bonding pad 130 has no slits in the embodiment, which does not limit the invention, and a bonding pad having a slit may be used instead.

A specific example of the bonding pad having a slit will now be described with reference to FIGS. 4 and 5. FIG. 4 is a plan view for showing the structure of a bonding pad used in a semiconductor device according to Modification 2. Also, FIG. 5 is a cross-sectional view for showing the structure of a bonding pad portion of the semiconductor device of Modification 2. It is noted that like reference numerals are used in FIG. 5 to refer to like elements used in the semiconductor device of the aforementioned embodiment. Accordingly, the same description as that made in the embodiment will be omitted in this modification.

The bonding pad 330 of FIG. 4 has slits 330s arranged in the form of a matrix.

When such a bonding pad is used and the uppermost layer dummy patterns 131 are uniformly provided in the uppermost layer non-interconnect region on the third interlayer insulating film 127 with a power electrode (not shown) provided with slits, the thermal stress can be more uniformly applied to respective transistors. Moreover, since the slits 330s are additionally provided to the bonding pad 330, the thermal stress caused by the bonding pad 330 can be uniformly applied to transistors disposed below the bonding pad 330 among the plural transistors formed on the semiconductor substrate 101. Therefore, the thermal stress can be more uniformly applied to the respective transistors. Accordingly, as compared with the aforementioned embodiment, the transistor characteristics of the respective transistors can be more uniformly varied.

Furthermore, when such a bonding pad is used, a wire 333 may be bonded, on the bonding pad 330, with a part thereof inserted into the slits 330s as shown in FIG. 5, and hence, the bonding strength can be improved and an open failure caused by disconnection of the wire 333 can be prevented.

### Modification 3

The dummy patterns 111, 119 and 126 are uniformly provided respectively in the whole non-interconnect regions of the insulating films 107, 115 and 123 in the semiconductor device of the aforementioned embodiment, which does not limit the invention.

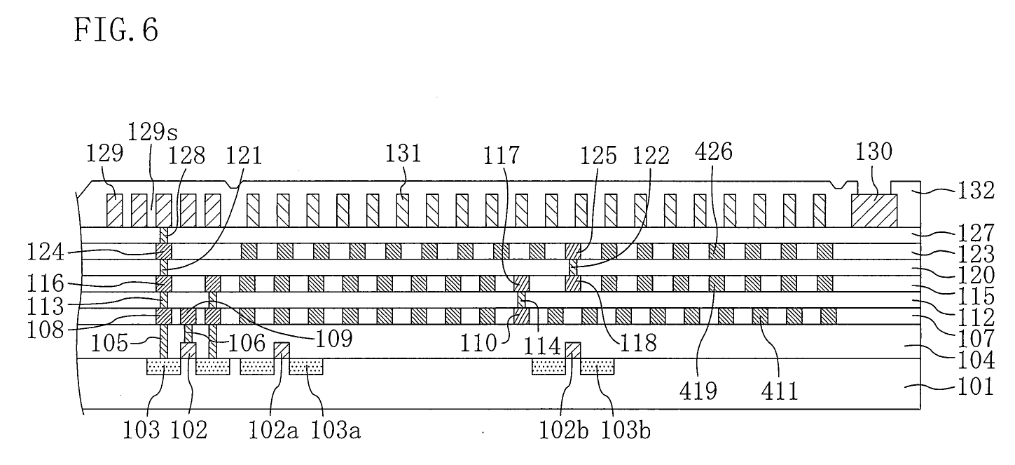

A semiconductor device including dummy patterns uniformly provided in the non-interconnect regions of the insulating films 107, 115 and 123 excluding regions disposed below the bonding pad 130 will now be described with reference to FIG. 6. FIG. 6 is a cross-sectional view of a semiconductor device according to Modification 3. It is noted that like reference numerals are used in FIG. 6 to refer to like elements used in the semiconductor device of the aforementioned embodiment. Accordingly, the same description as that made in the embodiment will be omitted in this modification.

As shown in FIG. 6, dummy patterns 411, 419 and 426 are uniformly disposed in the non-interconnect regions of the insulating films 107, 115 and 123 excluding regions disposed below the bonding pad 130. In other words, the dummy patterns 411, 419 and 426 are not provided in the regions of the insulating films 107, 115 and 123 disposed below the bonding pad 130.

In this manner, parasitic capacitance between the bonding pad 130 and the semiconductor substrate 101 can be prevented from being increased by dummy patterns disposed below the bonding pad 130.

### Modification 4

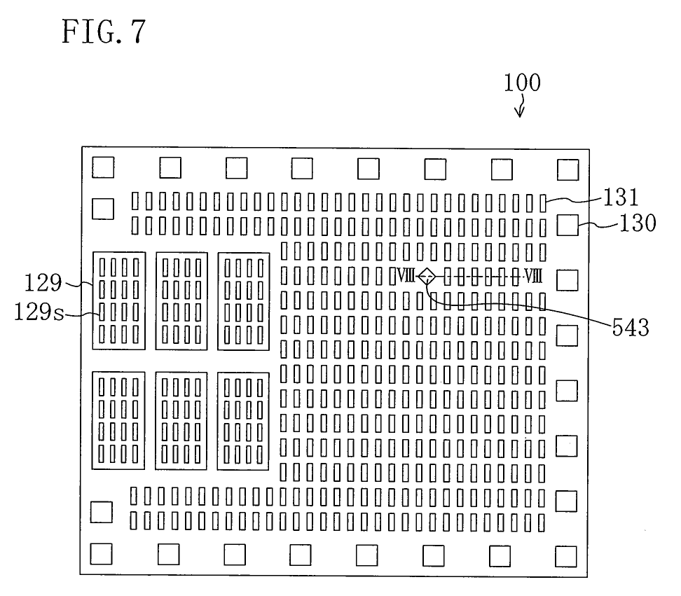

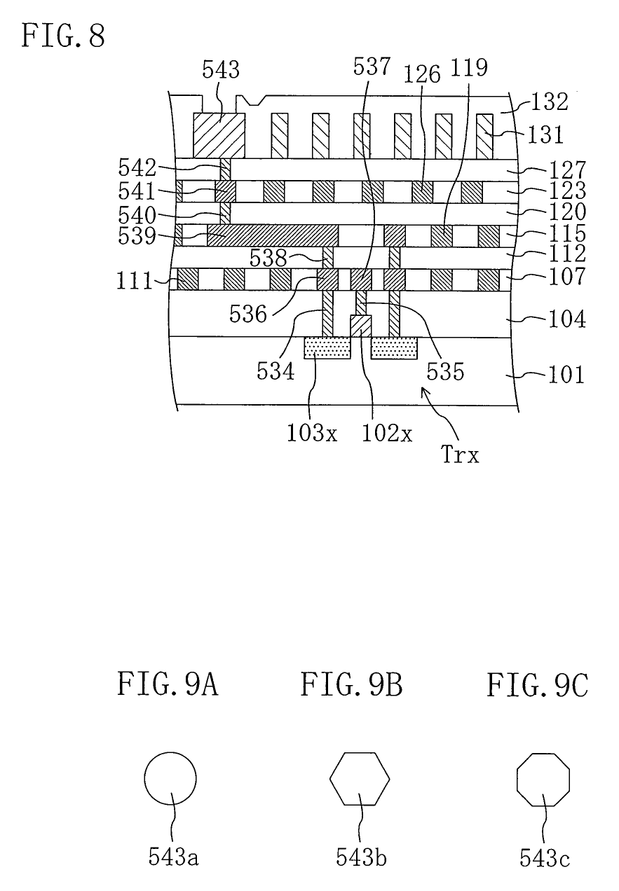

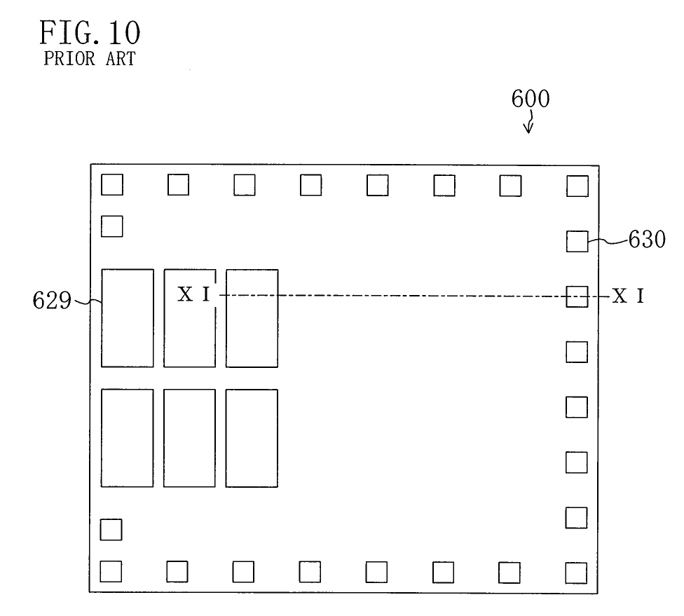

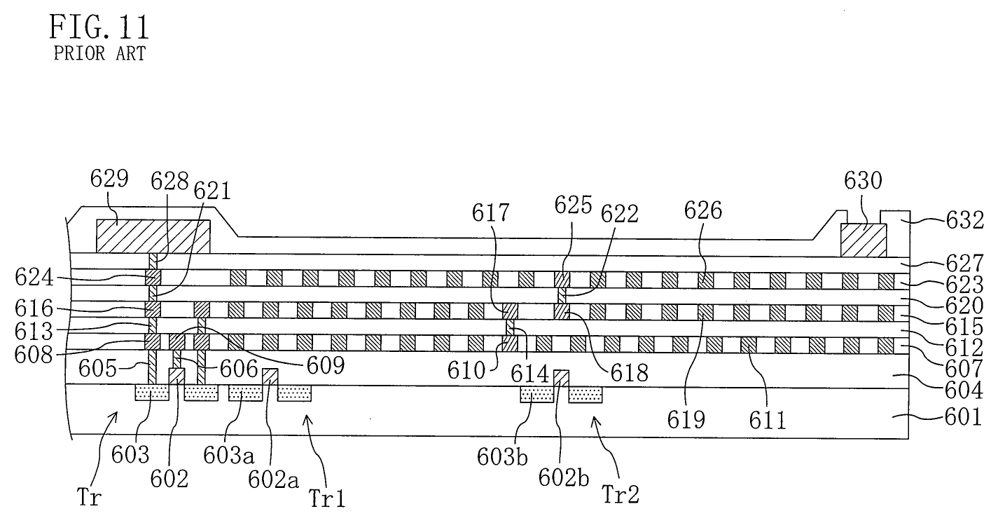

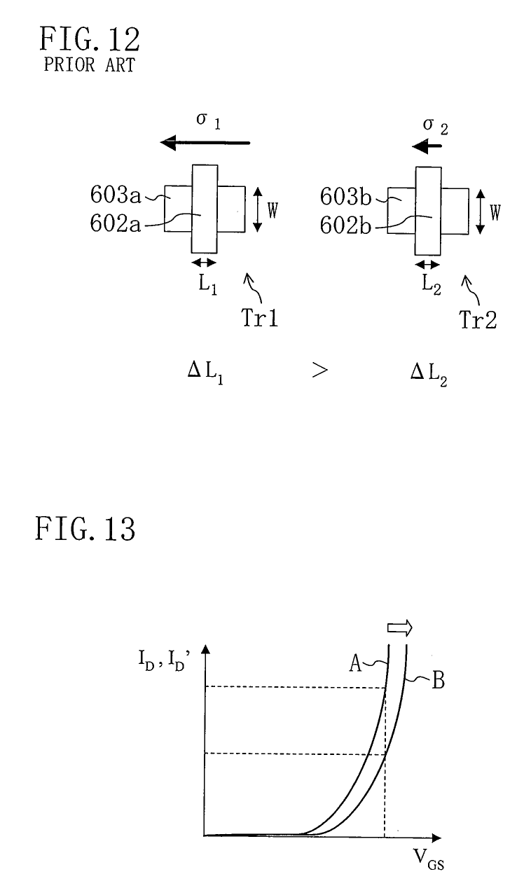

A semiconductor device including a testing monitor pad will now be described with reference to FIGS. 7 and 8. FIG. 7 is a plan view of a semiconductor device of Modification 4, and FIG. 8 is an enlarged cross-sectional view for showing the structure of a testing monitor pad portion of the semiconductor device of Modification 4 taken on line VIII-VIII of FIG. 7. It is noted that like reference numerals are used in FIGS. 7 and 8 to refer to like elements used in the semiconductor device of the aforementioned embodiment. Accordingly, the same description as that made in the embodiment will be omitted in this modification.

As shown in FIG. 7, a testing monitor pad 543 is provided on the semiconductor chip 100 in a region where the uppermost layer dummy patterns 131 are formed. Herein, the testing monitor pad 543 is used for evaluating the transistor characteristic of a transistor selected from the plural transistors formed on the semiconductor substrate.

As shown in FIG. 8, a gate electrode 102x is formed on the semiconductor substrate 101, and source/drain regions 103x are formed in the semiconductor substrate 101 on both sides of the gate electrode 102x. A contact plug 534 electrically connected to the source/drain region 103x and a contact plug 535 electrically connected to the gate electrode 102x are formed in the insulating film 104. An interconnect 536 electrically connected to the contact plug 534 and an interconnect 537 electrically connected to the contact plug 535 are formed in the first insulating film 107, and a contact plug 538 electrically connected to the interconnect 536 is formed in the first interlayer insulating film 112. An interconnect 539 electrically connected to the contact plug 538 is formed in the second insulating film 115, and a contact plug 540 electrically connected to the interconnect 539 is formed in the second interlayer insulating film 120. An interconnect 541 electrically connected to the contact plug 540 is formed in the third insulating film 123, and a contact plug 542 electrically connected to the interconnect 541 is formed in the third interlayer insulating film 127. The testing monitor pad 543 electrically connected to the contact plug 542 is formed on the third interlayer insulating film 127.

In this manner, the testing monitor pad 543 is electrically connected to a target transistor Trx including the gate electrode 102x and the source/drain regions 103x.

At this point, when a rectangular testing monitor pad (not shown) is provided on the third interlayer insulating film 127 in a region where the rectangular uppermost layer dummy patterns 131 are formed in the aforementioned embodiment, it may be difficult to distinguish the testing monitor pad from the uppermost layer dummy patterns 131 so as to discriminate the position of the testing monitor pad.

However, when the testing monitor pad 543 in a square shape is disposed, for example, with its apexes rotated by 45 degrees against the apexes of each rectangular uppermost layer dummy pattern 131 as shown in FIG. 7, the position of the testing monitor pad 543 can be easily discriminated.

Alternatively, when the shape of the testing monitor pad is different from the shape of the uppermost layer dummy pattern 131, more specifically, when a testing monitor pad 543a in a circular shape as shown in FIG. 9A, a testing monitor pad 543b in a hexagonal shape as shown in FIG. 9B or a testing monitor pad 543c in an octagonal shape as shown in FIG. 9C is used, the position of the testing monitor pad can be similarly easily discriminated.

It is noted that the present invention is not limited to the aforementioned embodiment and modifications but may be variously modified within the scope of the invention. Specifically, the shape of each uppermost layer dummy pattern 131 is not limited to the rectangular shape, and the same effect can be attained when it is in a circular or polygonal shape. Also, the arrangement of the rectangular uppermost layer dummy patterns 131 is not limited to that described above, and the same effect can be attained when the apexes of each uppermost layer dummy pattern 131 are rotated by 45 degrees against the apexes of the rectangular power electrode 129. Furthermore, the slit of the power electrode or the slit of the bonding pad is not limited to that described above. Moreover, although the three interconnect layers are provided beneath the uppermost layer interconnect in the aforementioned embodiment and modifications, the number of the interconnect layers is not limited to three.

As described so far, the present invention is useful for a semiconductor device including an uppermost layer interconnect with a large thickness.

What is claimed is:

1. A semiconductor device comprising:
a power device formed on a semiconductor substrate;
a plurality of transistors formed on the semiconductor substrate;
a first insulating film formed on the semiconductor substrate so as to cover the power device and the plurality of transistors;
an interconnect layer formed on the first insulating film and including a second insulating film, an interconnect formed in the second insulating film and dummy patterns formed in the second insulating film in a region where the interconnect is not formed;
a power electrode corresponding to an uppermost layer interconnect formed on the interconnect layer and electrically connected to the power device; and
uppermost layer dummy patterns uniformly provided on the interconnect layer in a region where the uppermost layer interconnect is not formed.

2. The semiconductor device of claim 1,
wherein the uppermost layer interconnect has a larger thickness than the interconnect.

3. The semiconductor device of claim 2,
wherein the uppermost layer interconnect has a thickness three times or more as large as a thickness of the interconnect.

4. The semiconductor device of claim 1,
wherein the uppermost layer interconnect is made of Cu.

5. The semiconductor device of claim 1,
wherein the power electrode has a slit.

6. The semiconductor device of claim 1, further comprising a bonding pad corresponding to the uppermost layer interconnect formed on the interconnect layer.

7. The semiconductor device of claim 6,
wherein the bonding pad has a slit.

8. The semiconductor device of claim 6,
wherein the dummy patterns are uniformly provided in a region of the second insulating film where the interconnect is not formed excluding a region disposed below the bonding pad.

9. The semiconductor device of claim 1, further comprising a testing monitor pad corresponding to the uppermost layer interconnect formed on the interconnect layer,
wherein the testing monitor pad is provided to be distinguishable from the uppermost layer dummy patterns.

10. The semiconductor device of claim 9,
wherein the testing monitor pad is in a different shape from the uppermost layer dummy patterns.
